(19) United States
(12) Patent Application Publication
(10) Pub. No.: US 2011/0109382 A1
(43) Pub. Date: May 12, 2011

(54) SEMICONDUCTOR APPARATUS

(75) Inventors: Sin Hyun JIN, Ichon-si (KR); Sang Jin Byeon, Ichon-si (KR)

(73) Assignee: Hynix Semiconductor Inc., Ichon-si (KR)

(21) Appl. No.: 12/650,648

(22) Filed: Dec. 31, 2009

(30) Foreign Application Priority Data
Nov. 12, 2009 (KR) 10-2009-0109055

(51) Int. Cl. H01L 25/00

(52) U.S. Cl. 327/565; 327/564; 257/621

(57) ABSTRACT

A semiconductor apparatus having a plurality of semiconductor chips is configured in such a manner that the plurality of semiconductor chips share one or more source voltages generated in one of the plurality of semiconductor chips.

### CROSS-REFERENCE TO RELATED APPLICATION

The present application claims priority under 35 U.S.C. §119(a) to Korean Patent Application No. 10-2009-0109055, filed on Nov. 12, 2009, in the Korean Intellectual Property Office, which is incorporated herein by reference in its entirety as if set forth in full.

### BACKGROUND

1. Technical Field

The present invention relates to a semiconductor apparatus, and more particularly, to a semiconductor apparatus of a three-dimensionally stacked structure and a control method thereof.

2. Related Art

Semiconductor apparatuses are typically used in the form of multi-chip packages each of which includes two or more chips so as to improve integration efficiency.

The multi-chip package is configured in such a manner that multiple chips are connected with one another using wires so that signals can be transferred among the chips.

FIG. 1 is a diagram illustrating a typical semiconductor apparatus 1. Referring to FIG. 1, the typical semiconductor apparatus 1 of a multi-chip package structure is manufactured such that multiple semiconductor chips CHIP_1 through CHIP_N are all connected to, a substrate 10 through wires 11.

Each of the multiple semiconductor chips CHIP_1 through CHIP_N has a power supply circuit and a peripheral circuit/a memory region so as to perform the same operational functions.

Therefore, the typical semiconductor apparatus of the multi-chip package structure has problems in that a layout margin decreases due to the necessity of multiple identical power supply circuits as well as the possible level differences between the source voltages across the multiple semiconductor chips CHIP_1 through CHIP_N.

### SUMMARY

In one embodiment of the present invention, a semiconductor apparatus having a plurality of semiconductor chips is configured in such a manner that the plurality of semiconductor chips share a source voltage generated in one of the plurality of semiconductor chips.

In another embodiment of the present invention, a semiconductor apparatus comprises a first semiconductor chip having a power supply circuit and a first functional circuit; a second semiconductor chip having a second functional circuit; and a voltage transfer element configured to supply a source voltage generated in the power supply circuit to the second functional circuit.

In another embodiment of the present invention, semiconductor apparatus comprises a first semiconductor memory chip having a power supply circuit and a first peripheral circuit/memory region; a second semiconductor memory chip having a second peripheral circuit/memory region; and a voltage transfer element configured to supply a source voltage generated in the power supply circuit to the second peripheral circuit/memory region.

In another embodiment of the present invention, a semiconductor apparatus comprises a master chip having a power supply circuit and a functional circuit for performing predetermined functions; a plurality of slave chips stacked on the master chip and each having a functional circuit for performing specified functions; and a plurality of through-silicon vias formed through the master chip and the plurality of slave chips, wherein a source voltage generated in the power supply circuit is supplied to functional circuits of the plurality of slave chips through some of the plurality of through-silicon vias.

### BRIEF DESCRIPTION OF THE DRAWINGS

Features, aspects, and embodiments are described in conjunction with the attached drawings, in which:

FIG. 1 is a diagram illustrating a typical semiconductor apparatus.

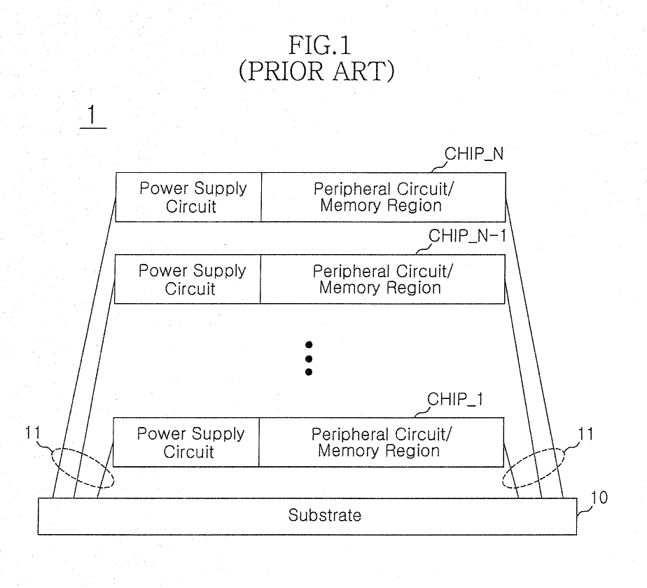

FIG. 2 is a diagram illustrating a semiconductor apparatus in accordance with an embodiment of the present invention.

FIG. 3 is a diagram illustrating an exemplary internal configuration of the semiconductor apparatus shown in FIG. 2.

FIG. 4 is a diagram illustrating a semiconductor apparatus in accordance with another embodiment of the present invention.

### DETAILED DESCRIPTION

Hereinafter, a semiconductor apparatus according to the present invention will be described below with reference to the accompanying drawings through preferred embodiments.

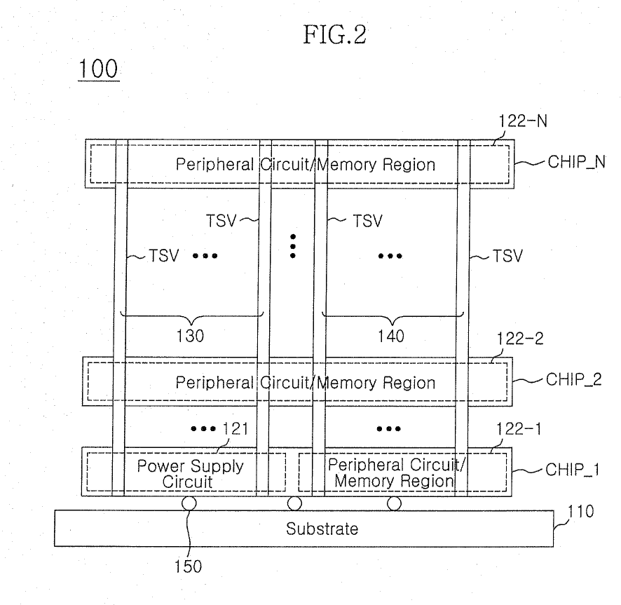

FIG. 2 is a diagram illustrating a semiconductor apparatus 100 in accordance with an embodiment of the present invention. Referring to FIG. 2, the semiconductor apparatus 100 in accordance with the embodiment has a three-dimensionally stacked structure.

The semiconductor apparatus 100 includes a substrate 110 and a plurality of semiconductor chips CHIP_1 through CHIP_N stacked on the substrate 110.

This embodiment of the present invention exemplifies a case when the plurality of semiconductor chips CHIP_1 through CHIP_N comprise chips that perform the same operation, for example, semiconductor memory chips such as dynamic random access memories (DRAMs).

The bottom semiconductor chip CHIP_1 is connected to the substrate 110 by way of electrodes 150, for example, ball grids.

The bottom semiconductor chip CHIP_1 includes a power supply circuit 121, and a peripheral circuit/a memory region 122-1 as functional circuit for performing the original functions of a semiconductor memory chip.

The remaining semiconductor chips CHIP_2 through CHIP_N other than the bottom semiconductor chip CHIP_1 do not include any power supply circuit but include only peripheral circuits/memory regions 122-2 through 122-N. Therefore, all the semiconductor chips CHIP_1 through CHIP_N share the power supply circuit 121 of the bottom semiconductor chip CHIP_1.

The memory region includes a plurality of memory cells, and a number of component parts for storing data to the memory cells and reading out the data stored in the memory cells, such as bit lines, word lines, various signal lines, sense amplifiers, and so forth.

Since the remaining semiconductor chips CHIP_2 through CHIP_N other than the bottom semiconductor chip CHIP_1 do not have the power supply circuit 121, chip area that should have been used for forming the power supply circuit 121 may be utilized as an extra space.

The plurality of semiconductor chips CHIP_1 through CHIP_N serving as voltage transfer elements are connected with one another by means of a first via group 130 and a second via group 140.

Each of the first via group 130 and the second via group 140 includes a plurality of through-silicon vias (TSVs).

The power supply circuit 121 of the bottom semiconductor chip CHIP_1 and the peripheral circuits/the memory regions 122-1 through 122-N of the plurality of semiconductor chips CHIP_1 through CHIP_N are connected to the first via group 130 and the second via group 140 through the wiring lines formed in the semiconductor chips CHIP_1 through CHIP_N.

The power supply circuit 121 of the bottom semiconductor chip CHIP_1 receives an external voltage VDD through the substrate 110 from an external device, and generates source voltages necessary for the operations of the peripheral circuits/the memory regions 122-1 through 122-N.

The source voltages necessary for the operations of the peripheral circuits/the memory regions 122-1 through 122-N can include, for example, a core voltage (VOCRE), a peripheral circuit voltage (VPERI), a bit line precharge voltage (VBLP), and boost voltages (VPP and VBB), but not limited thereto.

The source voltages generated in the power supply circuit 121 of the bottom semiconductor chip CHIP_1 are supplied to the peripheral circuit/the memory region 122-1 through the wiring lines formed in the bottom semiconductor chip CHIP_1.

Also, the source voltages generated in the power supply circuit 121 of the bottom semiconductor chip CHIP_1 are supplied to the peripheral circuits/the memory regions 122-2 through 122-N of the remaining semiconductor chips CHIP_2 through CHIP_N by way of the through-silicon vias of the first via group 130.

External signals such as commands, addresses, data and the like, other than the source voltages are supplied to the plurality of semiconductor chips CHIP_1 through CHIP_N by way of the substrate 110 and the through-silicon vias of the second via group 140.

The peripheral circuits/the memory regions 122-1 through 122-N of the plurality of semiconductor chips CHIP_1 through CHIP_N perform read, write and refresh operations in response to the external signals.

The semiconductor apparatus 100 according to the embodiment of the present invention is configured in such a manner that the plurality of semiconductor chips CHIP_1 through CHIP_N can share the power supply circuit 121.

Therefore, only the bottom semiconductor chip CHIP_1 is equipped with the power supply circuit 121 in addition to the peripheral circuit/the memory region 122-1, and the remaining semiconductor chips CHIP_2 through CHIP_N contain only the peripheral circuits/the memory regions 122-2 through 122-N.

The source voltages generated in the power supply circuit 121 of the bottom semiconductor chip CHIP_1 are shared by all the semiconductor chips CHIP_1 through CHIP_N. As means for supplying the source voltages generated in the power supply circuit 121 of the bottom semiconductor chip CHIP_1 to the semiconductor chips CHIP_2 through CHIP_N, the through-silicon vias are used.

Each of the through-silicon vias has a small resistance value and a large capacitance value. Thus, the source voltages generated in the power supply circuit 121 may be supplied to all the semiconductor chips CHIP_1 through CHIP_N at substantially the same levels as target values.

Meanwhile, before forming the through-silicon vias in the plurality of semiconductor chips CHIP_1 through CHIP_N, tests may be performed for each of the plurality of semiconductor chips CHIP_1 through CHIP_N.

At this time, since no power supply circuit is provided in the remaining semiconductor chips CHIP_2 through CHIP_N other than the bottom semiconductor chip CHIP_1, the tests may be performed by supplying various source voltages necessary for the operations of the semiconductor chips, from external testing equipments.

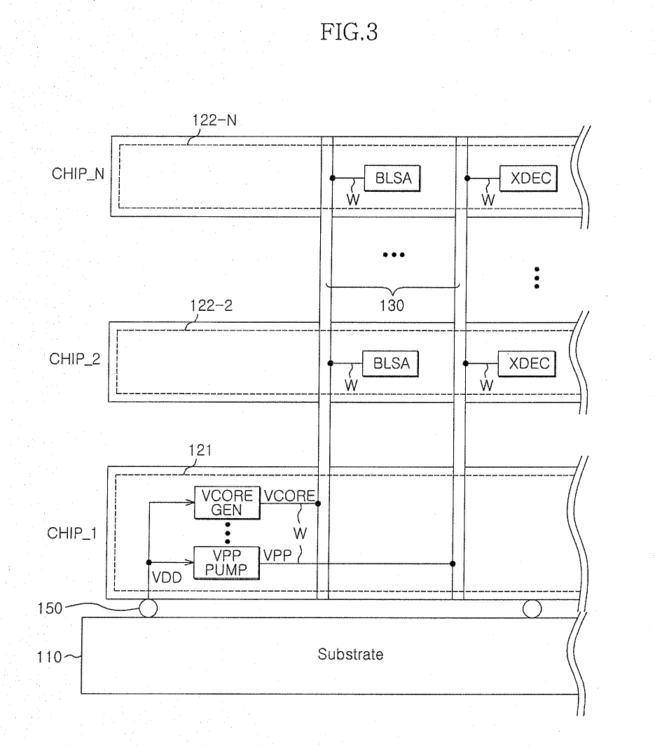

FIG. 3 is a diagram illustrating an exemplary internal configuration of the semiconductor apparatus 100 shown in FIG. 2. The semiconductor apparatus 100 according to the embodiment may be implemented as shown in FIG. 3.

For example, the power supply circuit 121 of the bottom semiconductor chip CHIP_1 may comprise a core voltage generator VCORE GEN for generating a core voltage (VOCRE) and a boost voltage pump VPP PUMP for generating a boost voltage (VPP).

The core voltage generator VCORE GEN and the boost voltage pump VPP PUMP are supplied with the external voltage VDD through the substrate 110, and generate the core voltage (VCORE) and the boost voltage (VPP), respectively.

The output terminals of the core voltage generator VCORE GEN and the boost voltage pump VPP PUMP are connected to the through-silicon vias of the first via group 130 by way of conductive wiring lines W, respectively.

Each of the semiconductor chips CHIP_2 through CHIP_N comprises a bit line sense amplifier BLSA and a row decoder XDEC. Although for the sake of convenience in explanation, only one sense amplifier BLSA and only one row decoder XDEC are shown in each semiconductor chip, those skilled in the art will understand that the semiconductor chip may include multiple sense amplifiers and/or multiple row decoders.

The bit line sense amplifier BLSA and the row decoder XDEC of each of the semiconductor chips CHIP_2 through CHIP_N are connected to the through-silicon vias of the first via group 130 by way of conductive wiring lines W, respectively.

Hence, the core voltage (VCORE) generated in the core voltage generator VCORE GEN of the bottom semiconductor chip CHIP_1 is commonly supplied to the bit line sense amplifiers BLSAs of the semiconductor chips CHIP_2 through CHIP_N by way of the through-silicon vias.

Also, the boost voltage (VPP) generated in the boost voltage pump VPP PUMP of the bottom semiconductor chip CHIP_1 is commonly supplied to the row decoders XDECs of the semiconductor chips CHIP_2 through CHIP_N by way of the through-silicon vias.

Each of the through-silicon vias has a small resistance value and a large capacitance value. Thus, the core voltage (VCORE) and the boost voltage (VPP) may be supplied to all the semiconductor chips CHIP_1 through CHIP_N at substantially the same levels as target values.

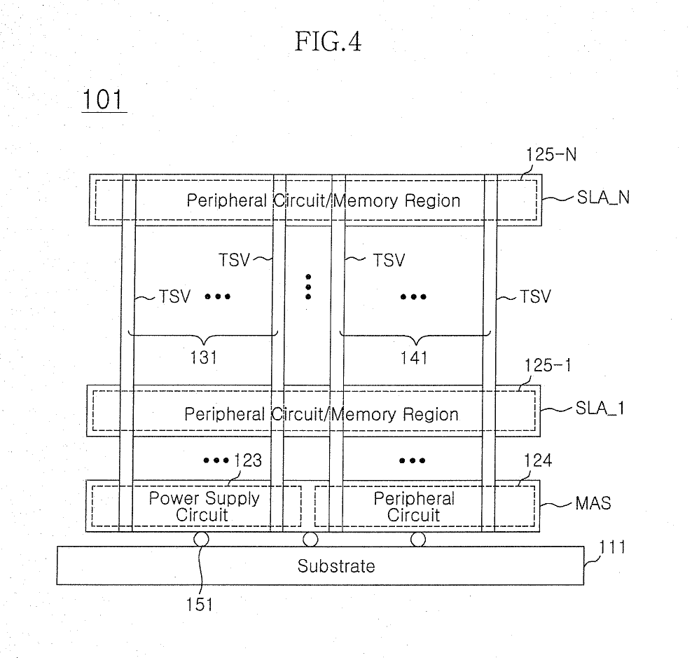

FIG. 4 is a diagram illustrating a semiconductor apparatus 101 in accordance with another embodiment of the present invention. Referring to FIG. 4, the semiconductor apparatus 101 in accordance with the embodiment has a three-dimensionally stacked structure.

The semiconductor apparatus 101 may comprise a substrate 111, a master chip MAS and a plurality of slave chips SLA_1 through SLA_N.

The master chip MAS is configured to perform the function of controlling the plurality of slave chips SLA_1 through SLA_N in response to commands from external devices such as a central processing unit (CPU) or a graphic processing unit (GPU).

The plurality of slave chips SLA_1 through SLA_N may comprise chips which perform the same functions, for example, dynamic random access memories (DRAMs).

The master chip MAS is connected to the substrate 111 by way of electrodes 151, for example, ball grids.

The master chip MAS includes a power supply circuit 123 and a peripheral circuit 124.

The configuration of the master chip MAS is made solely by the peripheral circuit 124, and any memory region is required for the configuration. This may make the configuration simple and the master chip MAS may be optimized for its original function, that is, a signal interfacing function with external devices, as required for the control of the slave chips SLA_1 through SLA_N.

The plurality of slave chips SLA_1 through SLA_N are not equipped with the power supply circuit 123 provided to the master chip MAS, and are equipped with peripheral circuits/memory regions 125-1 through 125-N only. Thus, the semiconductor apparatus 101 is configured in such a manner that the power supply circuit 123 may be used not only by the master chip MAS but also shared by all other slave chips SLA_1 through SLA_N.

The memory region includes a plurality of memory cells, and a number of component parts for storing data to the memory cells and reading out data stored in the memory cells, such as bit lines, word lines, various signal lines, sense amplifiers, and so forth.

Since all the slave chips SLA_1 through SLA_N other than the master chip MAS do not have the power supply circuit 123, chip area that should have been used for forming the power supply circuit 123 may be utilized as an extra space.

The master chip MAS and the plurality of slave chips SLA_1 through SLA_N are connected with one another by means of a first via group 131 and a second via group 141.

Each of the first via group 131 and the second via group 141 includes a plurality of through-silicon vias (TSVs).

The power supply circuit 123 and the peripheral circuit 124 of the master chip MAS and the peripheral circuits/the memory regions 125-1 through 125-N of the plurality of slave chips SLA_1 through SLA_N are connected to the first via group 131 and the second via group 141 through the wiring lines formed in the master chip MAS and the slave chips SLA_1 through SLA_N.

The power supply circuit 123 of the master chip MAS receives an external voltage VDD (not shown) through the substrate 111 from an external device, and generates source voltages necessary for the operations of the peripheral circuit 124 of the master chip MAS and the peripheral circuits/the memory regions 125-1 through 125-N of the plurality of slave chips SLA_1 through SLA_N.

The source voltages necessary for the operations of the peripheral circuit 124 of the master chip MAS and the peripheral circuits/the memory regions 125-1 through 125-N of the plurality of slave chips SLA_1 through SLA_N may comprise, for example, a core voltage (VOCRE), a peripheral circuit voltage (VPERI), a bit line precharge voltage (VBLP), and boost voltages (VPP and VBB).

The source voltages generated in the power supply circuit 123 of the master chip MAS are supplied to the peripheral circuit 124 of the master chip MAS through the wiring lines formed in the master chip MAS.

Also, the source voltages generated in the power supply circuit 123 of the master chip MAS are supplied to the peripheral circuits/the memory regions 125-1 through 125-N of the plurality of slave chips SLA_1 through SLA_N by way of the through-silicon vias of the first via group 131.

External signals such as commands, addresses, data and the like, other than the source voltages, are supplied to the master chip MAS and the plurality of slave chips SLA_1 through SLA_N by way of the substrate 111 and the through-silicon vias of the second via group 141.

The peripheral circuit 124 of the master chip MAS performs its original function in response to external signals, that is, the function of controlling the plurality of slave chips SLA_1 through SLA_N in response to commands from external devices.

The peripheral circuits/the memory regions 125-1 through 125-N of the plurality of slave chips SLA_1 through SLA_N perform their original functions in response to external signals, that is, perform read, write and refresh operations in case, for example, the plurality of slave chips SLA_1 through SLA_N comprise semiconductor memories.

The semiconductor apparatus 101 according to the embodiment of the present invention is configured in such a manner that the master chip MAS and the plurality of slave chips SLA_1 through SLA_N may share the power supply circuit 123.

That is to say, only the master chip MAS is equipped with the power supply circuit 123, and the remaining slave chips SLA_1 through SLA_N contain only the peripheral circuits/the memory regions 125-1 through 125-N.

As the master chip MAS does not have any memory region, the master chip MAS may be designed to be optimized for a signal interfacing function with external devices.

Because a memory region is not provided in the master chip MAS, power supply wiring lines may be easily laid in the master chip MAS.

The source voltages generated in the power supply circuit 123 are shared by the master chip MAS and the plurality of slave chips SLA_1 through SLA_N. As means for supplying the source voltages generated in the power supply circuit 123 of the master chip MAS to the plurality of slave chips SLA_1 through SLA_N, the through-silicon vias are used.

The through-silicon vias has a small resistance value and a large capacitance value. Thus, the source voltages generated in the power supply circuit 123 may be uniformly supplied to the master chip MAS and the plurality of slave chips SLA_1 through SLA_N.

Meanwhile, before forming the through-silicon vias in the master chip MAS and the plurality of slave chips SLA_1 through SLA_N, tests may be performed for each of the master chip MAS and the plurality of slave chips SLA_1 through SLA_N.

At this time, since no power supply circuit is provided in the plurality of slave chips SLA_1 through SLA_N other than the master chip MAS, the tests may be performed by supplying various source voltages necessary for the operations of the semiconductor chips, from external testing equipment.

As is apparent from the above descriptions, in the embodiments of the present invention, since a plurality of semiconductor chips can share a power supply circuit, a layout margin may be increased in semiconductor chips which do not need power supply circuits, and the levels of power external voltages in all the semiconductor chips may be made substantially uniform.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus having a plurality of semiconductor chips, wherein the plurality of semiconductor chips share a source voltage generated in one of the plurality of semiconductor chips.

2. The semiconductor apparatus according to claim 1, wherein the one of the plurality of semiconductor chips is configured to be supplied with an external voltage and generate the source voltage.

3. The semiconductor apparatus according to claim 1, wherein the plurality of semiconductor chips are configured to be supplied with the source voltage by way of through-silicon vias.

4. The semiconductor apparatus according to claim 1, wherein the one of the plurality of semiconductor chips is a master chip, and the remaining semiconductor chips are slave chips.

5. A semiconductor apparatus comprising:
a first semiconductor chip having a power supply circuit and a first functional circuit;
a second semiconductor chip having a second functional circuit; and
a voltage transfer element configured to supply a source voltage generated in the power supply circuit to the second functional circuit.

6. The semiconductor apparatus according to claim 5, wherein the power supply circuit is configured to be supplied with an external voltage and generate the source voltage.

7. The semiconductor apparatus according to claim 5, wherein the voltage transfer element comprises a through-silicon via.

8. The semiconductor apparatus according to claim 5, wherein the source voltage generated in the power supply circuit is supplied to the first functional circuit through an internal wiring line.

9. The semiconductor apparatus according to claim 5, wherein the first semiconductor chip is a master chip, and the second semiconductor chip is a slave chip.

10. A semiconductor apparatus comprising:
a first semiconductor memory chip having a power supply circuit and a first peripheral circuit/memory region;
a second semiconductor memory chip having a second peripheral circuit/memory region; and
a voltage transfer element configured to supply a source voltage generated in the power supply circuit to the second peripheral circuit/memory region.

11. The semiconductor apparatus according to claim 10, wherein the power supply circuit is configured to be supplied with an external voltage and generate the source voltage.

12. The semiconductor apparatus according to claim 10, wherein the voltage transfer element comprises a through-silicon via.

13. The semiconductor apparatus according to claim 10, wherein the source voltage generated in the power supply circuit is supplied to the first peripheral circuit/memory region through an internal wiring line.

14. The semiconductor apparatus according to claim 10, wherein the first semiconductor chip is a master chip, and the second semiconductor chip is a slave chip.

15. A semiconductor apparatus comprising:
a master chip having a power supply circuit and a functional circuit for performing predetermined functions;
a plurality of slave chips stacked on the master chip and each having a functional circuit for performing specified functions; and
a plurality of through-silicon vias formed through the master chip and the plurality of slave chips,
wherein a source voltage generated in the power supply circuit is supplied to functional circuits of the plurality of slave chips through some of the plurality of through-silicon vias.

16. The semiconductor apparatus according to claim 15, wherein the power supply circuit is configured to be supplied with an external voltage and generate the source voltage.

17. The semiconductor apparatus according to claim 15, wherein the source voltage generated in the power supply circuit is supplied to the functional circuit of the master chip through internal wiring lines.
